(19) United States
(12) Patent Application Publication
(10) Pub. No.: US 2019/0094636 A1
(43) Pub. Date: Mar. 28, 2019

(54) DISPLAY APPARATUS AND METHOD OF MANUFACTURING THE SAME

(71) Applicant: Samsung Display Co., Ltd., Yongin-si (KR)

(72) Inventors: Hoon Kang, Suwon-si (KR); Sikwang Kim, Daegu (KR); Jeongmin Park, Seoul (KR); Yong-Hoon Yang, Hwaseong-si (KR); Saehee Han, Seoul (KR)

(21) Appl. No.: 15/933,226

(22) Filed: Mar. 22, 2018

(30) Foreign Application Priority Data
Sep. 27, 2017 (KR) 10-2017-0125499

(51) Int. Cl. G02F 1/1362; G02F 1/1335; G02F 1/1368; H01L 29/49; H01L 27/12; G02F 1/1343

(52) U.S. Cl. CPC G02F 1/136209; G02F 1/133516; G02F 1/136286; G02F 1/1368; H01L 29/4908; H01L 27/1262; G02F 2201/40; G02F 1/13439; G02F 2201/52; G02F 2001/136222; G02F 2001/136295; G02F 2201/123; H01L 27/124

(57) ABSTRACT

A display apparatus includes a first color filter, a second color filter spaced apart from the first color filter, and a light blocking pattern disposed between the first color filter and the second color filter, and making contact with the first color filter and the second color filter. A thickness of the light blocking pattern is smaller than a thickness of the first color filter or a thickness of the second color filter. An upper surface of the light blocking pattern is lower than an upper surface of the first or second color filter by a first height, and the light blocking pattern does not include a photosensitive material.

### CROSS-REFERENCE TO RELATED APPLICATION

This application claims priority to and the benefit of Korean Patent Application No. 10-2017-0125499, filed on Sep. 27, 2017, the entire content of which is incorporated herein by reference.

### BACKGROUND

### 1. Field

Example embodiments of the present disclosure relate to a display apparatus and a method of manufacturing the display apparatus. For example, example embodiments of the present disclosure relate to a display apparatus including a color filter and a light blocking pattern and a method of manufacturing the display apparatus.

### 2. Description of the Related Art

Recently, a display apparatus having light weight and small size has been manufactured. A cathode ray tube (CRT) display apparatus has been used due to a performance and a competitive price. However the CRT display apparatus has a weakness or disadvantage with a size or portability. Therefore a display apparatus such as a plasma display apparatus, a liquid crystal display apparatus and an organic light emitting display apparatus has been highly regarded due to small size, light weight and low-power-consumption.

The display apparatus includes a light blocking pattern to block light. The light blocking pattern with a large line width may decrease an aperture ratio of the display apparatus. The light blocking pattern may be formed by photoresist process using an additional mask, so that there has been a problem that the manufacturing cost is increased.

### SUMMARY

One or more example embodiments of the present disclosure provides a display apparatus including a light blocking pattern having a thin line width formed without additional photoresist process to improve display quality by

One or more example embodiments of the present disclosure also provide a method of manufacturing the display apparatus.

According to an example embodiment of the present disclosure, a display apparatus includes a first color filter, a second color filter spaced apart from the first color filter, and a light blocking pattern disposed between the first color filter and the second color filter, and making contact with the first color filter and the second color filter. A thickness of the light blocking pattern is smaller than a thickness of the first color filter or a thickness of the second color filter. An upper surface of the light blocking pattern is lower than an upper surface of the first or second color filter by a first height, and the light blocking pattern does not include a photosensitive material.

In an example embodiment, the light blocking pattern may be formed using a light blocking material which includes a binder, a solvent and a black pigment.

In an example embodiment, each of the thickness of the first color filter and the thickness of second color filter may be about 1.0 to 4.0 μm (micrometer), and the thickness of the light blocking pattern may be about 0.3 to 4.0 μm.

In an example embodiment, the display apparatus may further include a lower substrate, an upper substrate facing the lower substrate, and a liquid crystal layer disposed between the lower base substrate and the upper base substrate. The first color filter and the second color filter may be disposed between the lower substrate and the liquid crystal layer.

In an example embodiment, the display apparatus may further include a data line disposed between the lower base substrate and the light blocking pattern, and extending in a second direction which is perpendicular (e.g., substantially perpendicular) to a first direction.

In an example embodiment, the display apparatus may further include a pixel electrode disposed on the first and second color filters. The pixel electrode may be spaced apart from the light blocking pattern.

In an example embodiment, the pixel electrode may partially overlap the light blocking pattern, so that an edge of the pixel electrode may make contact with the light blocking pattern.

In an example embodiment, the first filter may extend in the second direction corresponding to a plurality of pixels. The second filter may extend in the second direction corresponding to a plurality of pixels. The first color filter and the second color filter may be spaced apart from each other in the first direction.

In an example embodiment, the display apparatus may further include a gate pattern including a gate electrode disposed between the first and second color filters and the lower base substrate. The gate electrode may not overlap the light blocking pattern, and overlap the first or second color filter.

In an example embodiment, the gate pattern may include molybdenum tantalum oxide (MoTaOx).

According to an example embodiment of the present disclosure, a method of manufacturing a display apparatus includes forming a first color filter and a second color filter on a base substrate, the second color filter being spaced apart from the first color filter on a base substrate, forming a light blocking material between the first color filter and the second color filter, and forming a light blocking pattern by removing an upper portion of the light blocking material using developer.

In an example embodiment, each of thickness of the first color filter and the thickness of second color filter may be about 1.0 to 4.0 μm (micrometer). Thickness of the light blocking pattern may be about 0.3 to 4.0 μm.

In an example embodiment, the light blocking material may be provided between the first color filter and the second color filter by using an ink jet method during the forming of the light blocking material.

In an example embodiment, the upper portion of the blocking material may be removed until an upper surface of the light blocking pattern becomes lower than an upper surface of the first or second color filter by a first height during the forming of the light blocking pattern.

In an example embodiment, forming the first and second color filter may include coating a photosensitive resist on the base substrate, and forming the first color filter by exposure and development using a mask, and coating a photosensitive resist on the base substrate on which the first color filter is formed, and forming the second color by exposure and development using a mask.

In an example embodiment, a light blocking layer may cover upper surfaces of the first and second color filters during the forming of the light blocking material

In an example embodiment, the base substrate may be a lower base substrate. The method may further include preparing an upper base substrate, and forming a liquid crystal layer between the upper base substrate and the lower base substrate.

In an example embodiment, the method may further include forming a data pattern including a data line on the base substrate before forming the first and second color filters. The data line may overlap the light blocking pattern.

In an example embodiment, the method may further include forming a gate pattern including a gate electrode on the base substrate before forming the first and second color filters. The gate electrode may not overlap the light blocking pattern, and overlap the first or second color filter.

In an example embodiment, the gate pattern may include molybdenum tantalum oxide (MoTaOx).

According to the example embodiments of the present disclosure, a first color filter and a second color filter which is spaced apart from the first color filter are formed on a base substrate. A light blocking material is formed between the first and second color filters. The light blocking material is developed using a developer to remove an upper portion of the light blocking material, so that a light blocking pattern is formed. Accordingly a display apparatus may be manufactured.

At this time, since the development process is continued until the upper surface of the light blocking pattern becomes lower than the upper surface of the first or second color filter, the light blocking material that has remained unintentionally in a pixel area may be removed. Therefore, the light blocking material does not remain in the pixel area, so that the display quality can be improved.

In addition, since the light blocking pattern is formed by providing the light blocking material by the inkjet method and then developing it, a line width of the light blocking pattern may be smaller than that of other light blocking patterns formed by an inkjet method. Accordingly, the aperture ratio of the display apparatus may be improved, and the display quality can be improved.

In addition, an edge of the light blocking pattern proceeds in the developing process and the light blocking pattern is linearly formed along a second direction according to a shape of a groove formed between the first color filter and the second color filter. The quality of the shape of the light blocking pattern may be improved as compared with the case where the ink is dropped by the inkjet method. Accordingly, problems such as light leakage around the light blocking pattern may be solved, and the display quality of the display apparatus may be improved.

It is to be understood that both the foregoing general description and the following detailed description are exemplary and explanatory and are intended to provide further explanation of the subject matter of the present disclosure as claimed

### BRIEF DESCRIPTION OF THE DRAWINGS

The above and other features of the subject matter of the present disclosure will become more apparent by describing in more detail example embodiments thereof with reference to the accompanying drawings, in which:

FIG. 1 is a plan view illustrating arrangement of a color filter and a light blocking pattern of a display apparatus according to an example embodiment of the present disclosure;

FIG. 2 is a cross-sectional view taken along a line I-I′ of FIG. 1;

FIG. 3 is a cross-sectional view taken along a line II-II′ of FIG. 1;

FIG. 4 is a cross-sectional view illustrating a display apparatus according to an example embodiment of the present disclosure;

FIG. 5 is a cross-sectional view illustrating a display apparatus according to an example embodiment of the present disclosure;

FIGS. 6A-6I are cross-sectional views illustrating a method of manufacturing the display apparatus of FIGS. 1-3;

FIGS. 7A-7C are cross-sectional views illustrating another method of manufacturing the display apparatus of FIGS. 1-3;

FIG. 8 is a cross-sectional view illustrating display apparatus of FIG. 4; and

FIGS. 9A-9D are cross-sectional views illustrating another method of manufacturing the display apparatus of FIG. 5.

### DETAILED DESCRIPTION

Hereinafter, embodiments of the present disclosure will be explained in more detail with reference to the accompanying drawings.

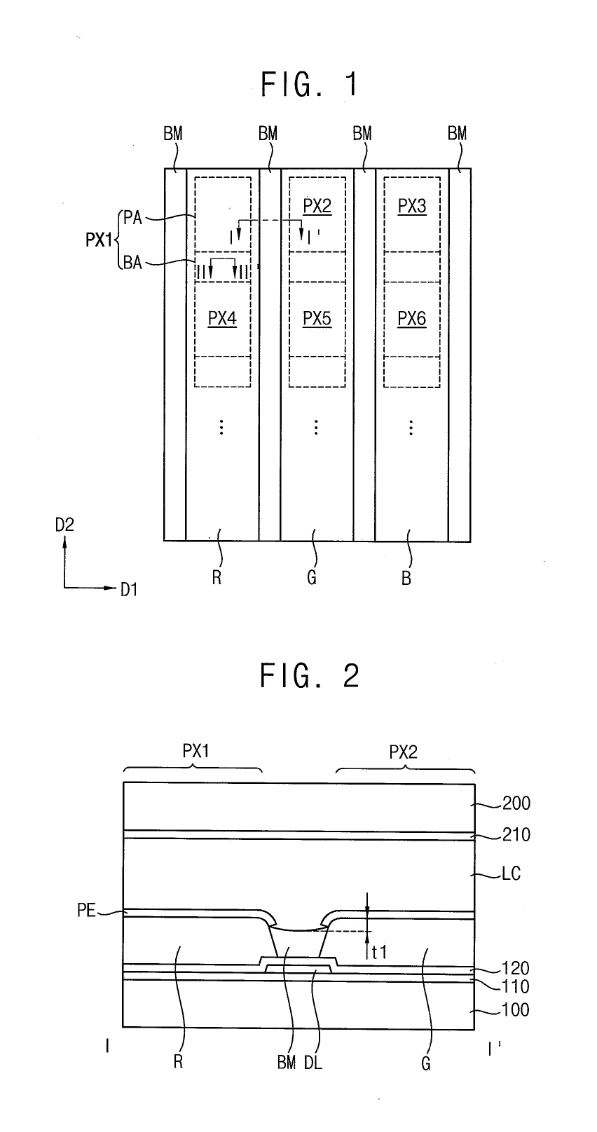

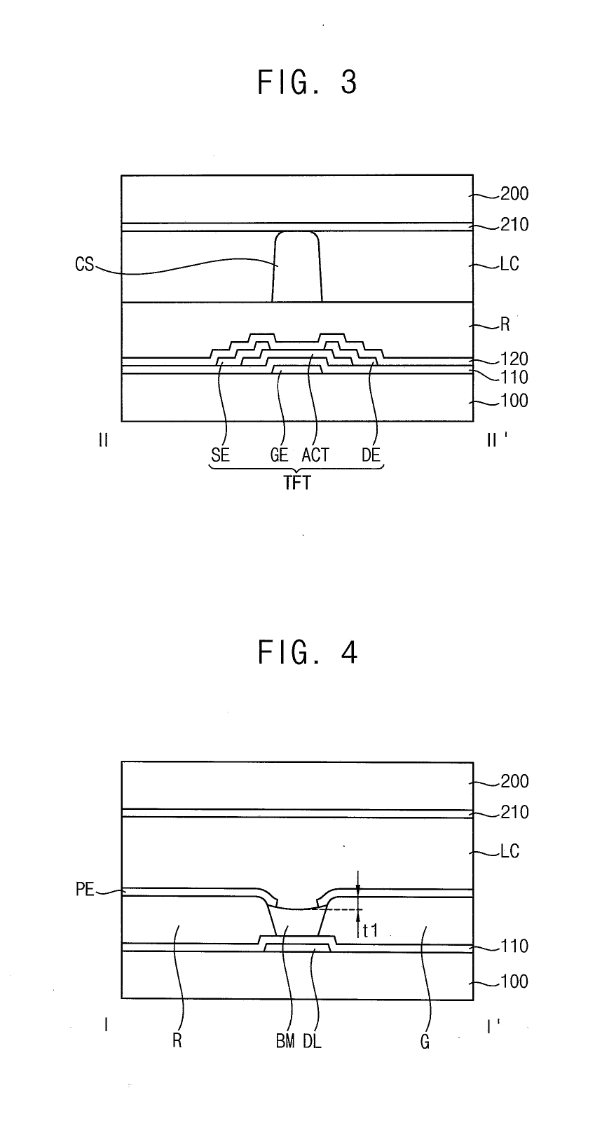

FIG. 1 is a plan view illustrating arrangement of a color filter and a light blocking pattern of a display apparatus according to an example embodiment of the present disclosure. FIG. 2 is a cross-sectional view taken along a line I-I′ of FIG. 1. FIG. 3 is a cross-sectional view taken along a line II-II′ of FIG. 1.

Referring to FIGS. 1-3, the display apparatus may include a lower base substrate 100, a gate pattern, a first insulation layer 110, an active pattern ACT, a data pattern, a second insulation layer 120, a first color filter R, a second color filter G, a third color filter B, a light blocking pattern BM, a pixel electrode PE, a column spacer CS, a liquid crystal layer LC, a common electrode 210 and an upper base substrate 200.

Referring again to FIG. 1, the display apparatus may include a plurality of pixels arranged in a matrix form. The pixels may include first to sixth pixels PX1, PX2, PX3, PX4, PX5 and PX6 arranged in a first direction D1 and a second direction D2 which is perpendicular (e.g., substantially perpendicular) to the first direction D1.

The first to third pixels PX1, PX2 and PX3 may be arranged in the first direction D1 in order. The fourth to sixth pixels PX4, PX5 and PX6 may be arranged in the first direction D1 in order. The fourth pixel PX4 may be disposed adjacent to the first pixel PX1 in the second direction D2. The fifth pixel PX5 may be disposed adjacent to the second pixel PX2 in the second direction D2. The sixth pixel PX6 may be disposed adjacent to the third pixel PX3 in the second direction D2.

Each of the first to sixth pixels PX1 to PX6 may include a pixel area PA through which light is transmitted for displaying an image, and a light blocking area BA in which a circuit such as a thin film transistor is disposed, so that the light is not transmitted through the light blocking area BA. The light blocking area BA may be disposed adjacent to the pixel area PA in the second direction D2. The light blocking areas BA of the first through third pixels PX1, PX2 and PX3 arranged in the first direction D1 may be extend in the first direction D1.

The first color filter R may be disposed corresponding to the first and fourth pixels PX1 and PX4. Thus, the first the first color filter R may extend in the second direction D2.

The second color filter G may be disposed corresponding to the second and fifth pixels PX1 and PX5. Thus, the second color filter G may extend in the second direction D2.

The third color filter B may be disposed corresponding to the third and sixth pixels PX1 and PX5. Thus, the third color filter B may extend in the second direction D2.

The light blocking pattern BM which extends in the second direction D2 may be disposed between the first color filter R and the second color filter G, and between the second color filter G and the third color filter B. Thus, the light blocking pattern BM may extends in the second direction D2 and may be disposed between two pixels adjacent each other in the first direction D1.

Accordingly, the first to third color filters R, G and B may be arranged in a strip shape.

Referring to FIGS. 2-3, the lower base substrate 100 may be disposed on the backlight unit. The lower base substrate 100 may include a transparent insulation substrate. For example, the lower base substrate 100 may include a glass substrate, a quartz substrate, a transparent resin substrate, etc. Examples of the transparent resin substrate for the lower base substrate 100 may include polyimide-based resin, acryl-based resin, polyacrylate-based resin, polycarbonate-based resin, polyether-based resin, sulfonic acid containing resin, polyethyleneterephthalate-based resin, etc.

The gate pattern may be disposed on the lower base substrate 100. The gate pattern may include a conductive material which can block light. For example, the gate pattern may be formed using a metal, an alloy, a metal nitride, a conductive metal oxide, or the like. The gate pattern may include a gate electrode GE and a signal line for transferring a signal for driving a pixel such as a gate line. The gate pattern may be disposed in the light blocking area BA of the pixels, and the gate pattern may contain molybdenum tantalum oxide (MoTaOx) in order to effectively block the light. For example, the gate pattern may include a metal layer and a molybdenum tantalum oxide layer formed on the metal layer.

The first insulation layer 110 may be disposed on the lower base substrate 100 on which the gate pattern is disposed. The first insulating layer 110 may be formed using an inorganic insulating material such as silicon oxide or metal oxide. For example, the first insulating layer 110 may be formed using silicon oxide (SiOx), silicon nitride (SiNx), silicon oxynitride (SiOxNy), aluminum oxide (AlOx), tantalum oxide (TaOx), hafnium oxide (HfOx), zirconium oxide (ZrOx), titanium oxide (TiOx), etc. These may be used alone or in a combination thereof. In example embodiments, the first insulating layer 110 may be uniformly (e.g., substantially uniformly) formed on the lower base substrate 100 along a profile of the gate pattern. Here, the first insulating layer 110 may have a substantially small thickness, such that a stepped portion may be formed at a portion of the first insulating layer 110 adjacent to the gate pattern. In some example embodiments, the first insulation layer 110 may have a relatively large thickness for sufficiently covering the gate pattern, so that the first insulation layer 110 may have a substantially level surface.

The active pattern ACT may be disposed on the first insulation layer 110 to overlap the gate electrode GE. The active pattern ACT may include a source area and a drain area each of which is impurity-doped area, and further include a channel area between the source area and the drain area.

The data pattern may be disposed on the active pattern ACT. The data pattern may include a conductive material which can block light. For example, the data pattern may be formed using a metal, an alloy, a metal nitride, a conductive metal oxide, or the like. The data pattern may include a source electrode SE and a drain electrode DE of a thin film transistor TFT and a signal line for transferring a signal for driving a pixel such as a data line DL. The source electrode SE and the drain electrode DE, the active pattern ACT and the gate electrode GE may be included in the thin film transistor TFT.

The second insulation layer 120 may be disposed on the first insulation layer 110 on which the data pattern is disposed. The second insulation layer 120 may be formed using inorganic or organic insulation material. When the second insulation layer 120 includes the inorganic insulating material, the second insulation layer 120 may be formed using silicon oxide or metal oxide. For example, the second insulation layer 120 may be formed using silicon oxide (SiOx), silicon nitride (SiNx), silicon oxynitride (SiOxNy), aluminum oxide (AlOx), tantalum oxide (TaOx), hafnium oxide (HfOx), zirconium oxide (ZrOx), titanium oxide (TiOx), etc. These may be used alone or in a combination thereof. In example embodiments, the second insulation layer 120 may be uniformly (e.g., substantially uniformly) formed on the first insulation layer 110 along a profile of the data pattern. Here, the second insulation layer 120 may have a substantially small thickness, such that a stepped portion may be formed at a portion of the second insulation layer 120 adjacent to the data pattern. In some example embodiments, the second insulation layer 120 may have a relatively large thickness for sufficiently covering the data pattern, so that the second insulation layer 120 may have a substantially level surface.

The first color filter R may be disposed on the second insulation layer 120 corresponding to the first pixel PX1 and the forth pixel PX4. The first color filter R is for providing red light to light transmitted through the liquid crystal layer LC. The first color filter R may be a red color filter.

The second color filter G may be disposed on the second insulation layer 120 corresponding to the second pixel PX2 and the fifth pixel PX5. The second color filter G is for providing green light to light transmitted through the liquid crystal layer LC. The second color filter G may be a green color filter.

The third color filter B may be disposed on the second insulation layer 120 corresponding to the third pixel PX3 and the sixth pixel PX6. The third color filter B is for providing blue light to light transmitted through the liquid crystal layer LC. The third color filter B may be a blue color filter.

The first color filter R and the second color filter G may be spaced apart from each other on the data line DL. The second color filter G and the third color filter B may be spaced apart from each other on the data line DL.

The light blocking pattern BM may be disposed between the first color filter R and the second color filter G, and between the second color filter G and the third color filter B. The light blocking pattern BM may be disposed on the second insulation layer 120 with being overlapped with the data line DL. Thus, the light blocking pattern BM may make contact (e.g., physical contact) with a portion of the second insulation layer 120 which overlaps the data line DL and side surfaces of the first and second color filters R, G or the second and third color filters G, B.

Thickness of the light blocking pattern BM may be smaller than thickness of the first, second or third color filters R, G, B. Thus, an upper surface of the light blocking pattern BM may be lower than an upper surface of the first, second or third color filters R, G, B. For example, the upper surface of the light blocking pattern BM may be lower than the upper surface of the first, second, or third color filters R, G, B by a first height t1. Here, the thickness of the first, second or third color filter R, G, B may be about 1.0 to 4.0 μm (micrometer), and the thickness of the light blocking pattern BM may be 0.3 to 4.0 μm.

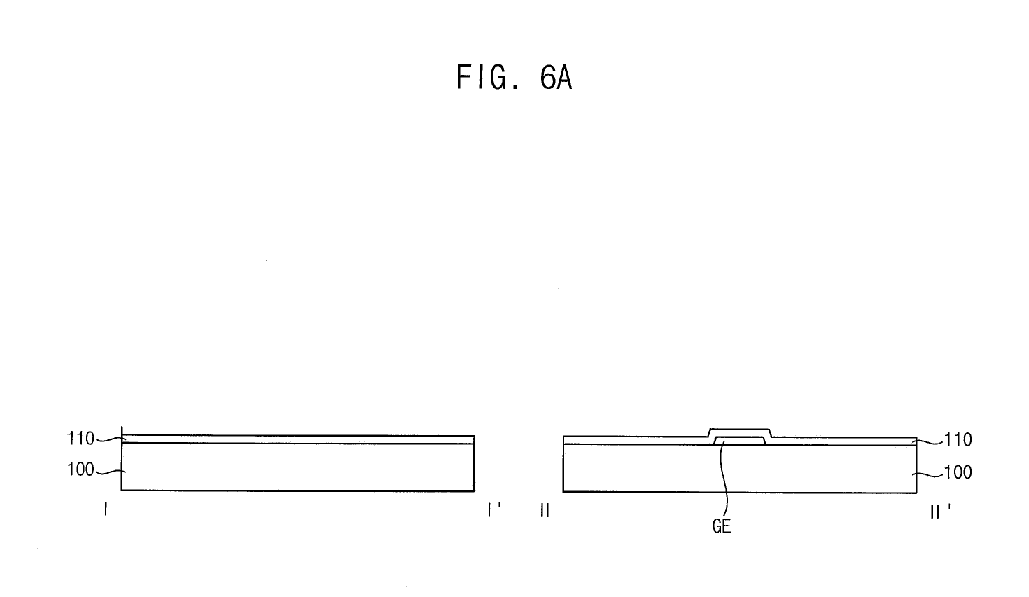

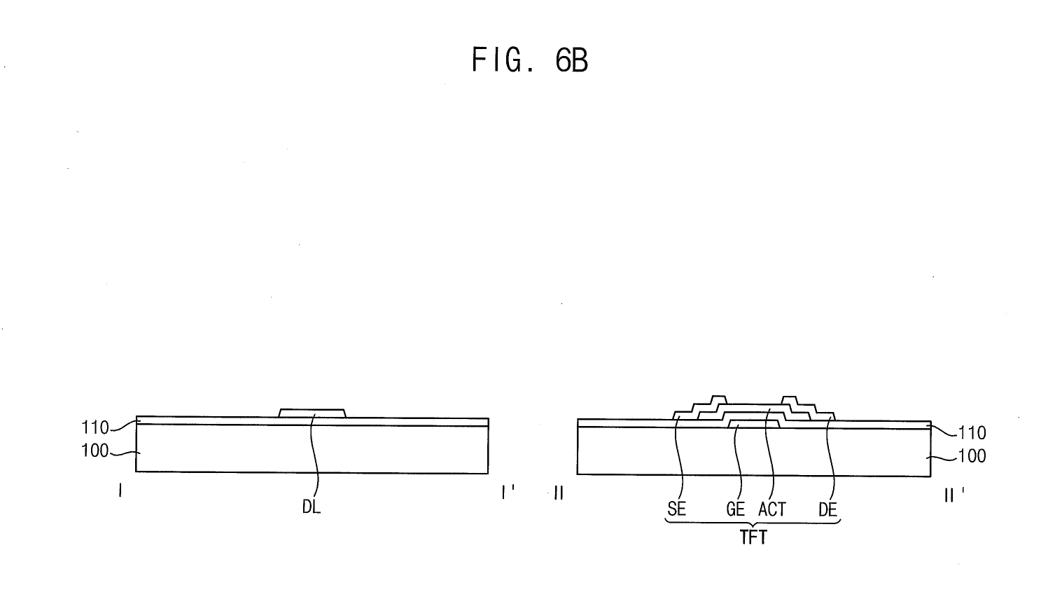

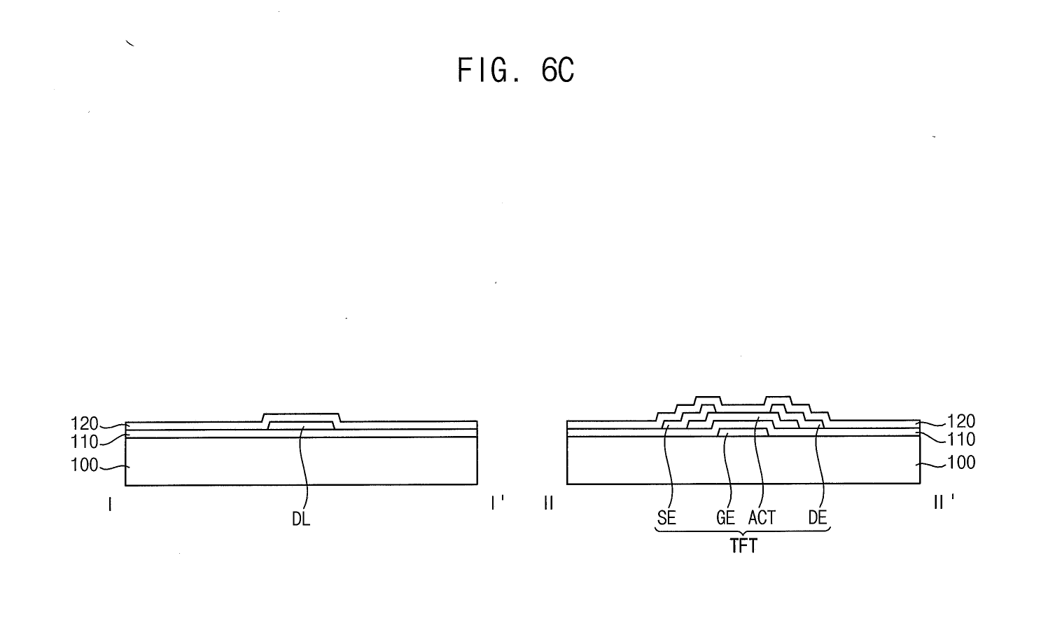

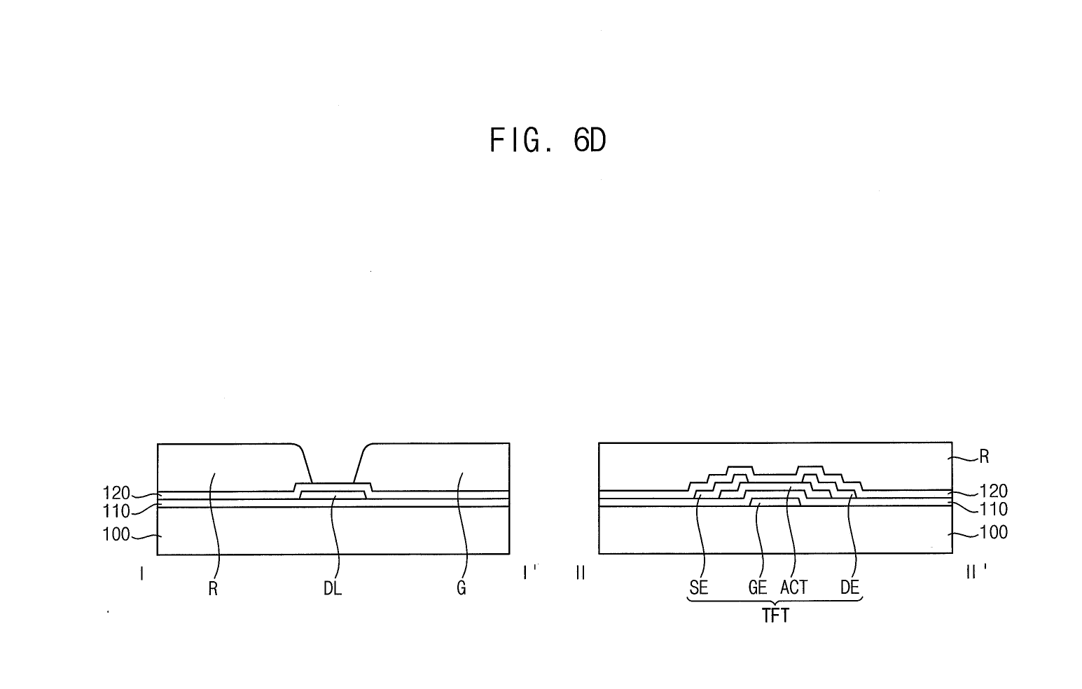

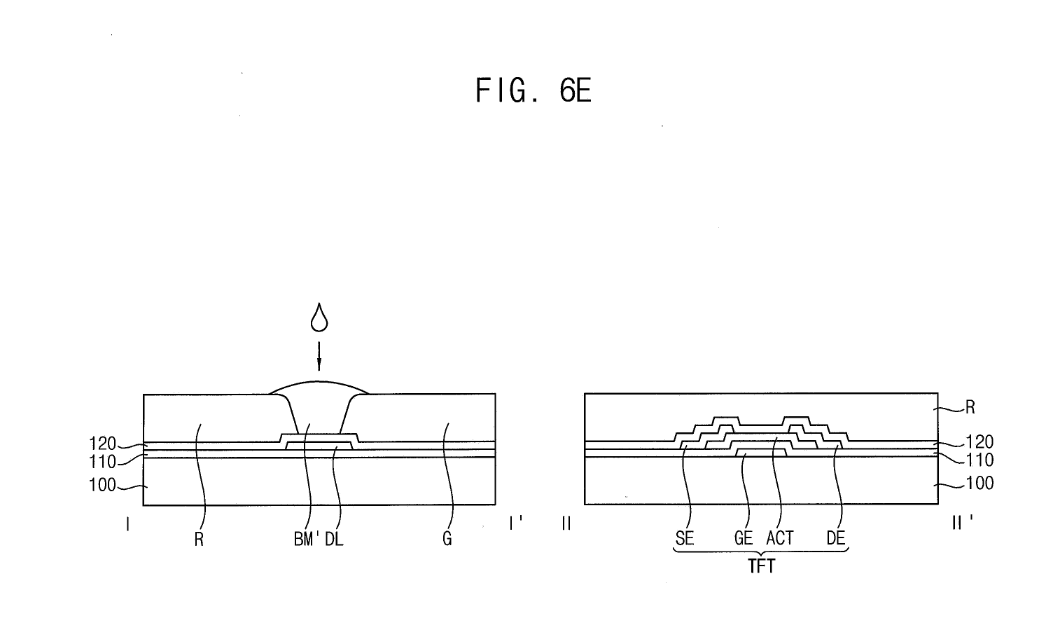

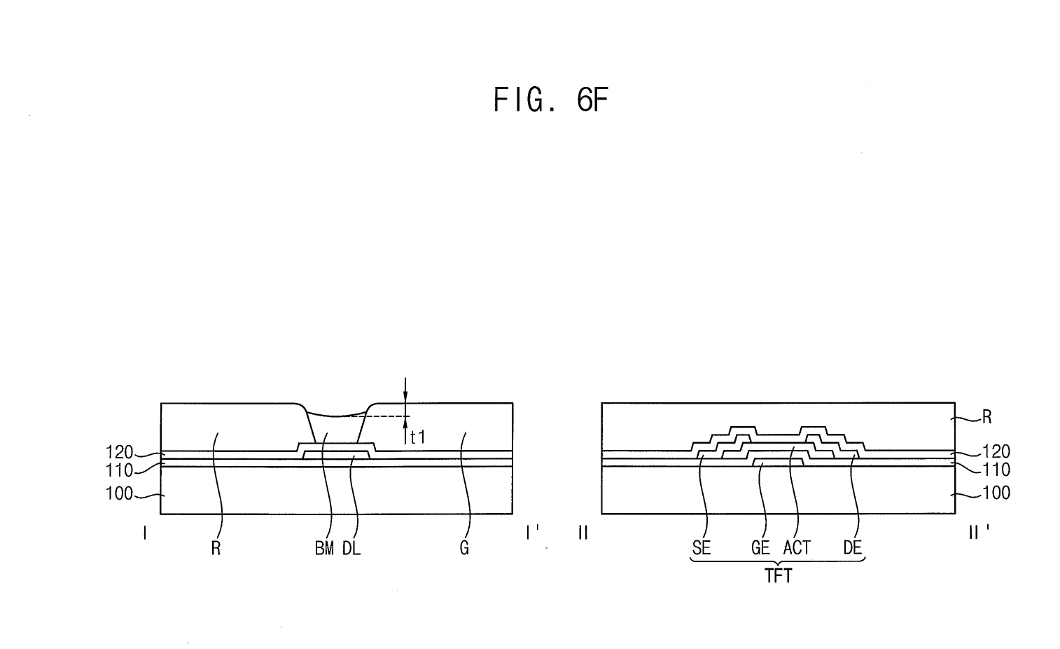

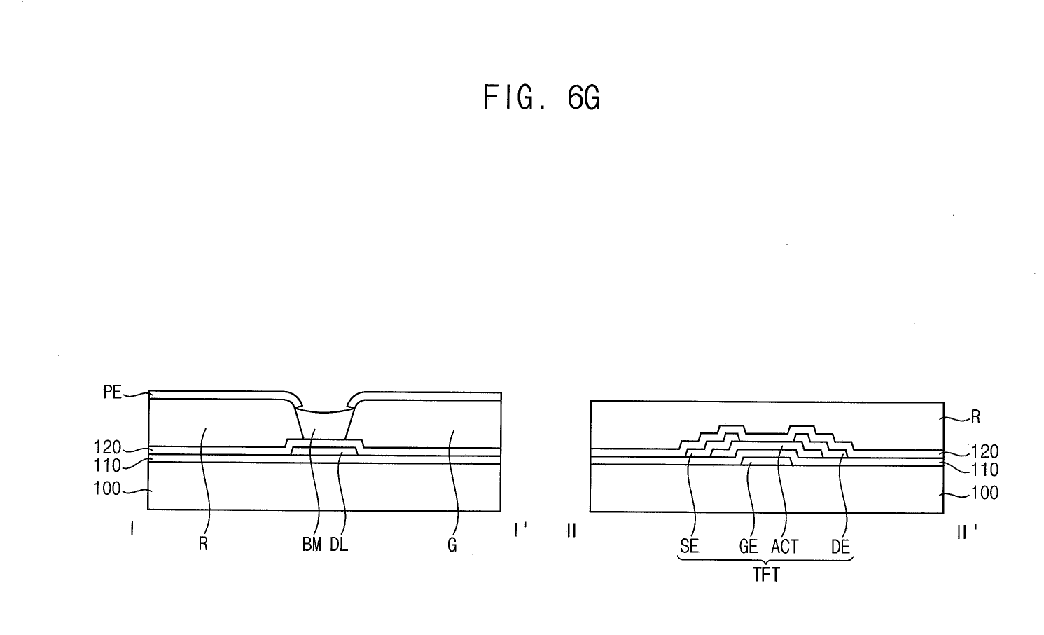

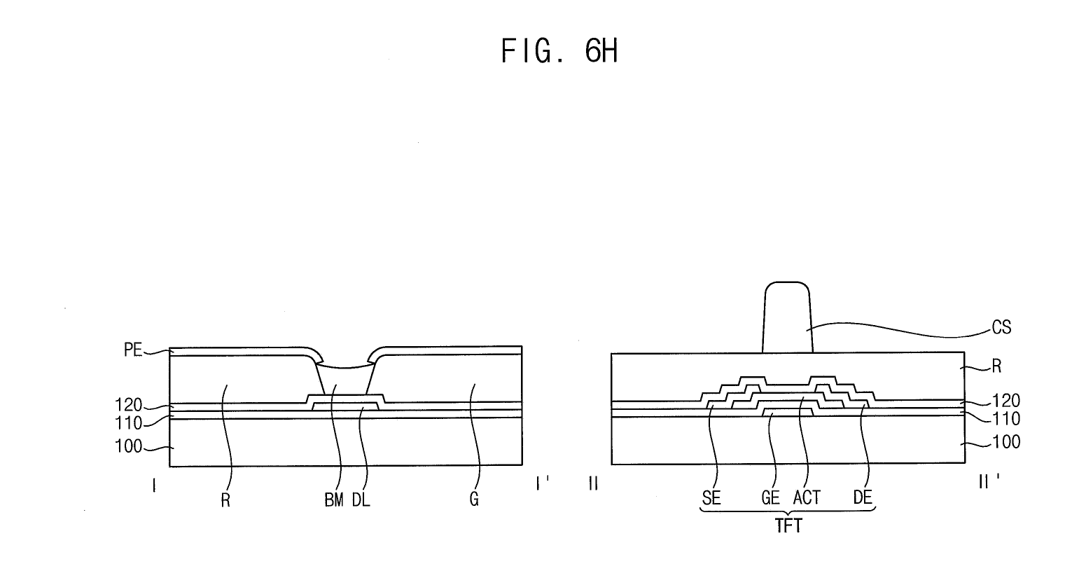

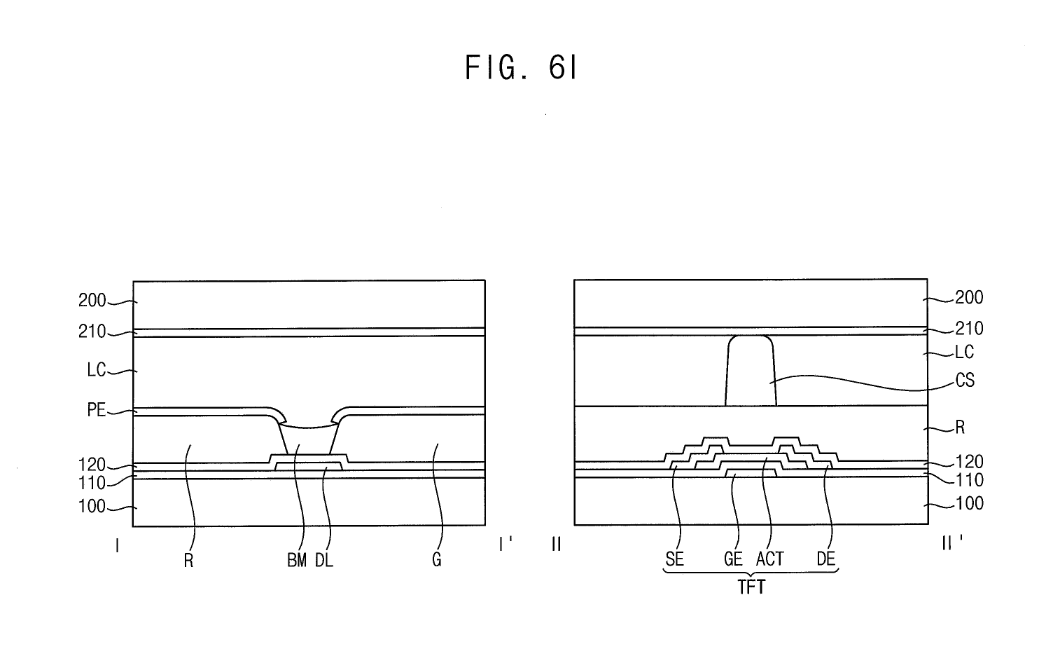

The light blocking pattern BM may include a binder, a solvent and a black pigment such as carbon black. The light blocking pattern BM may not include a photosensitive material such as a positive photoresist or a negative photoresist since an exposure process for patterning is not necessary as described herein with reference to FIGS. 6E-6F. Accordingly, since the light blocking pattern BM according to the present embodiment does not require an exposure process, a black pigment or the like is further included in the light blocking pattern BM as compared with a light blocking pattern material requiring an exposure process for patterning. Thus, light blocking performance of the light blocking pattern BM according to the present embodiment may be improved.

The pixel electrode PE may be disposed on the first to third color filters R, G and B. The pixel electrode PE may be electrically coupled to (e.g., electrically connected to) the thin film transistor TFT through a contact hole formed through the first, second or third color filter R, G, B and the second insulation layer 120. The pixel electrode PE may include a transparent conductive material. For example, the pixel electrode PE may include indium tin oxide (ITO), indium zinc oxide (IZO) and etc.

The pixel electrode PE may not overlap the light blocking pattern BM. In the present embodiment, an edge of the pixel electrode PE is coincidence with an edge of the light blocking pattern BM. In some example embodiment, the edge of the pixel electrode PE may be spaced apart from the edge of the light blocking pattern BM.

The column spacer CS may be disposed on the first, second or third color filters R, G, B on which the pixel electrode PE is disposed. The column spacer CS may maintain cell gap.

The liquid crystal layer LC may be disposed between the pixel electrode PE and the common electrode 210. The liquid crystal layer LC may include liquid crystal molecules having optical anisotropy. The liquid crystal molecules may be driven by an electric field to transmit or block light passing through the liquid crystal layer LC to display an image.

The common electrode 210 may be disposed on the liquid crystal layer LC. A common voltage may be applied to the common electrode 210. The common electrode 210 may include a transparent conductive material. For example, the common electrode 210 may include indium tin oxide (ITO), indium zinc oxide (IZO) and etc.

The upper base substrate 200 may be disposed on the common electrode 210. The upper base substrate 200 may include a transparent insulation substrate. For example, the upper base substrate 200 may include a glass substrate, a quartz substrate, a transparent resin substrate, etc. Examples of the transparent resin substrate for the upper base substrate 200 may include polyimide-based resin, acryl-based resin, polyacrylate-based resin, polycarbonate-based resin, polyether-based resin, sulfonic acid containing resin, polyethyleneterephthalate-based resin, etc.

The display apparatus may further include lower and upper alignment layers for alignment of the liquid crystal molecules. The lower and upper alignment layers may be disposed between the liquid crystal layer LC and the pixel electrode PE, and between the liquid crystal layer LC and the common electrode 210.

The display apparatus may further include a lower polarizing layer on the lower base substrate 100 and an upper polarizing layer on the upper base substrate 200. The display apparatus may further include a backlight unit disposed under the lower base substrate 100 to provide light to the liquid crystal layer LC.

FIG. 4 is a cross-sectional view illustrating a display apparatus according to an example embodiment of the present disclosure.

Referring to FIG. 4, the display apparatus may be substantially same as the display apparatus of FIGS. 1-3 except that a pixel electrode overlaps a light blocking pattern. Thus, any further detailed descriptions concerning the same elements will not be repeated here.

The display apparatus may include a lower base substrate 100, a gate pattern, a first insulation layer 110, an active pattern, a data pattern, a second insulation layer 120, a first color filter R, a second color filter G, a third color filter, a light blocking pattern BM, a pixel electrode PE, a column spacer, a liquid crystal layer LC, a common electrode 210 and an upper base substrate 200.

The pixel electrode PE may be disposed on the first to third color filters R, G. A portion of an edge of the pixel electrode PE may be disposed on the light blocking pattern BM, so that the pixel electrode PE may be partially overlapped with the light blocking pattern BM. An upper surface of the light blocking pattern BM may be lower than an upper surface of the first, second or third color filter R, G by a first height t1.

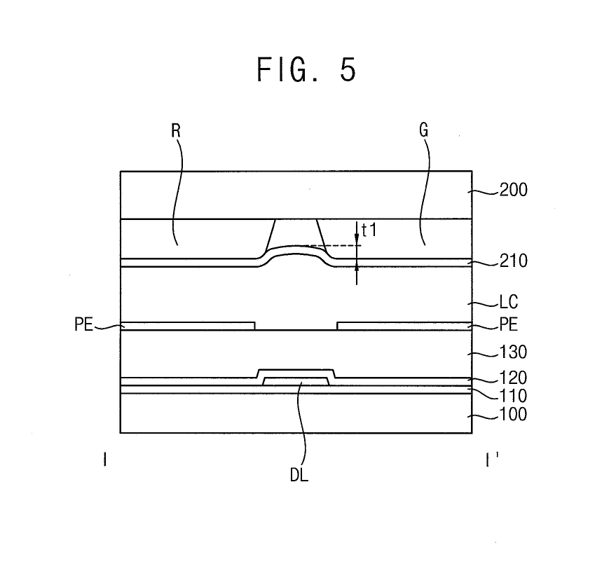

FIG. 5 is a cross-sectional view illustrating a display apparatus according to an example embodiment of the present disclosure.

Referring to FIG. 5, the display apparatus may be substantially same as the display apparatus of FIGS. 1-3 except that positions of a color filter and a light blocking pattern and the display apparatus further includes a third insulation layer 130. Thus, any further detailed descriptions concerning the same elements will not be repeated here.

The display apparatus may include a lower base substrate 100, a gate pattern, a first insulation layer 110, an active pattern, a data pattern, a second insulation layer 120, a third insulation layer 130, a pixel electrode PE, a column spacer, a liquid crystal layer LC, a common electrode 210, a first color filter R, a second color filter G, a third color filter, a light blocking pattern BM, and an upper base substrate 200.

The gate pattern may be disposed on the lower base substrate 100. The first insulation layer 110 may be disposed on the lower base substrate 100 on which the gate pattern is disposed. The active pattern and the data pattern including a data line DL may be disposed on the first insulation layer 110. A second insulation layer 120 may be disposed on the first insulation layer 110 on which the active pattern and the data pattern is disposed.

The third insulation layer 130 may be disposed on the second insulation layer 120. The third insulation layer 130 may be formed using inorganic or organic insulation material. The third insulation layer 130 may have a substantially level surface. Thus, the third insulation layer 130 may be a planarization layer.

The pixel electrode PE may be disposed on the second insulation layer 120. The liquid crystal layer LC may be disposed on the pixel electrode PE. The common electrode 210 may be disposed on the liquid crystal layer LC. The first color filter R, the second color filter G, the third color filter and the light blocking pattern BM may be disposed on the common electrode 210. The upper substrate 200 may be disposed on the first color filter R, the second color filter G, the third color filter and the light blocking pattern BM.

FIGS. 6A-6I are cross-sectional views illustrating a method of manufacturing the display apparatus of FIGS. 1-3.

Referring to FIG. 6A, a gate pattern may be formed on a lower substrate 100. The gate pattern may include a gate electrode GE and a signal line for transferring a signal for driving a pixel such as a gate line.

A conductive layer may be formed on the lower base substrate 100, and then the conductive layer may be patterned by a photolithography process or an etching process using an additional etching mask. Hence, the gate pattern may be provided on the lower base substrate 100. Here, the conductive layer may be formed by a printing process, a sputtering process, a CVD process, a pulsed laser deposition (PLD) process, a vacuum evaporation process, an atomic layer deposition (ALD) process, etc.

A first insulation layer 110 may be formed on the lower base substrate 100 on which the gate pattern is formed. The first insulation layer 110 may be formed by a spin coating process, a CVD process, a PECVD process, a HDP-CVD process, etc.

Referring to FIG. 6B, the active pattern and the data pattern may be formed on the first insulation layer 110. The data pattern may include a data line DL.

An active layer may be formed on the first insulation layer 110, and then the active layer may be patterned by a photolithography process or an etching process using an additional etching mask. Hence, the active pattern may be provided on the first insulation layer 110. A conductive layer may be formed on the first insulation layer 110 on which the active pattern is formed, and then the conductive layer may be patterned by a photolithography process or an etching process using an additional etching mask. Hence, the data pattern may be provided. In some example embodiment, the active layer and the conductive layer may be formed on the first insulation layer 110. Then, the conductive layer and the active layer may be patterned to form the active pattern and the data pattern.

Referring to FIG. 6C, a second insulation layer 120 may be formed on the first insulation layer 110 on which the data pattern and the active pattern are formed. The second insulation layer 120 may be formed by a spin coating process, a CVD process, a PECVD process, a HDP-CVD process, etc.

Referring to FIG. 6D, a first color filter R, a second color filter G, and a third color filter may be formed on the second insulation layer 120. The first color filter R, the second color filter G and the third color filter may be formed in order.

For example, a photosensitive resist may be coated on the second insulation layer 120, and then the photosensitive resist may be pattern by exposure and development using a mask to form the first color filter R. And then, a photosensitive resist may be coated on the second insulation layer 120 on which the first color filter R is formed, and then the photosensitive resist may be pattern by exposure and development using a mask to form the second color filter G. And then, a photosensitive resist may be coated on the second insulation layer 120 on which the first color filter R and the second color filter G are formed, and then the photosensitive resist may be pattern by exposure and development using a mask to form the third color filter. In some example embodiment, the first to third color filters R, G may be formed by other methods such as an inkjet method.

At this time, the first color filter R and the second color filter G (or the second color filter G and the third color filter, or the third color filter and the first color filter R) are spaced apart from each other on the data lien DL, so that a groove may be formed between the first color filter R and the second color filter G. Thus, the groove may form a space for a light blocking material which will be described herein with reference to FIG. 6E.

Referring to FIG. 6E, the light blocking material BM′ may be provided to the groove which is between the first color filter R and the second color filter G on the second insulation layer 120 by an inkjet method. The light blocking material BM′ may include a binder, a solvent and a black pigment such as carbon black. Since the light blocking material BM′ does not require an exposure process for patterning, it may not include a photosensitive material such as a positive photoresist or a negative photoresist.

At this time, the light blocking material BM′ may be sufficiently provided to cover a portion of the upper surface of the first color filter R and the second color filter G. Accordingly, the upper surface of the light blocking material BM′ may be higher than the upper surface of the first color filter R and the upper surface of the second color filter G.

Referring to FIG. 6F, the light blocking material BM′ may be developed using a developer to remove an upper portion of the light blocking material BM′. Thus, the light blocking pattern BM may be formed. The upper surface of the light blocking pattern BM may be lower than the upper surface of the first or second color filter R or G by a first height t1. Here, the light blocking pattern BM having proper height can be formed by changing development condition such as a type (or kind) of developer and developing time.

In addition, since the development process is continued until the upper surface of the light blocking pattern BM becomes lower than the upper surface of the first or second color filter R or G, the light blocking material that has remained unintentionally may be removed. Therefore, the light blocking material does not remain in the pixel area, so that the display quality can be improved.

In addition, since the light blocking pattern BM is formed by providing the light blocking material BM′ by the inkjet method and then developing it, a line width of the light blocking pattern BM may be smaller than that of other light blocking patterns formed by an inkjet method. Accordingly, the aperture ratio of the display apparatus may be improved, and the display quality can be improved.

In addition, an edge of the light blocking pattern BM proceeds in the developing process and the light blocking pattern BM is linearly formed along a second direction (see D2 in FIG. 1) according to the shape of the groove formed between the first color filter R and the second color filter G. The quality of the shape of the light blocking pattern BM may be improved as compared with the case where the ink is dropped by the inkjet method. Accordingly, problems such as light leakage around the light blocking pattern BM may be solved, and the display quality of the display apparatus may be improved.

Referring to FIG. 6G, a pixel electrode PE may be formed on the first to third color filters R, G. The pixel electrode PE may be formed by patterning a transparent conductive layer which is formed on the first to third color filters R, G. The transparent conductive layer may be formed by a sputtering process, a CVD process, a PLD process, a vacuum evaporation process, an ALD process, a printing process, etc.

In this embodiment, the pixel electrode PE is formed after forming the light blocking pattern BM. However, the pixel electrode PE may be formed before forming the light blocking pattern BM if necessary.

Referring to FIG. 6H, a column spacers CS may be formed on the first to third color filters R, G on which the pixel electrode PE is formed. The column spacer CS may be formed by a general photoresist process using a photosensitive material, and thus it is not necessary that column spacer CS includes a black pigment such as carbon black.

Referring to FIG. 6I, a common electrode 210 may be formed on the upper base substrate 200. And then, a liquid crystal layer LC may be formed between the base substrate 200 on which the common electrode 210 is formed and the lower base substrate 100 on which the pixel electrode PE is formed to manufacture the display apparatus.

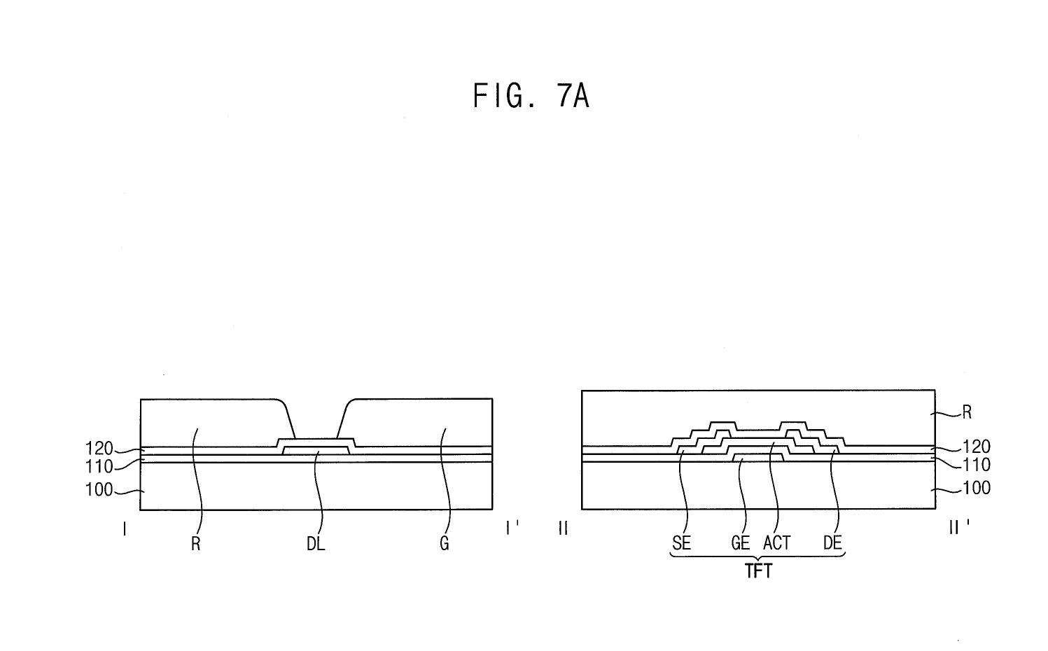

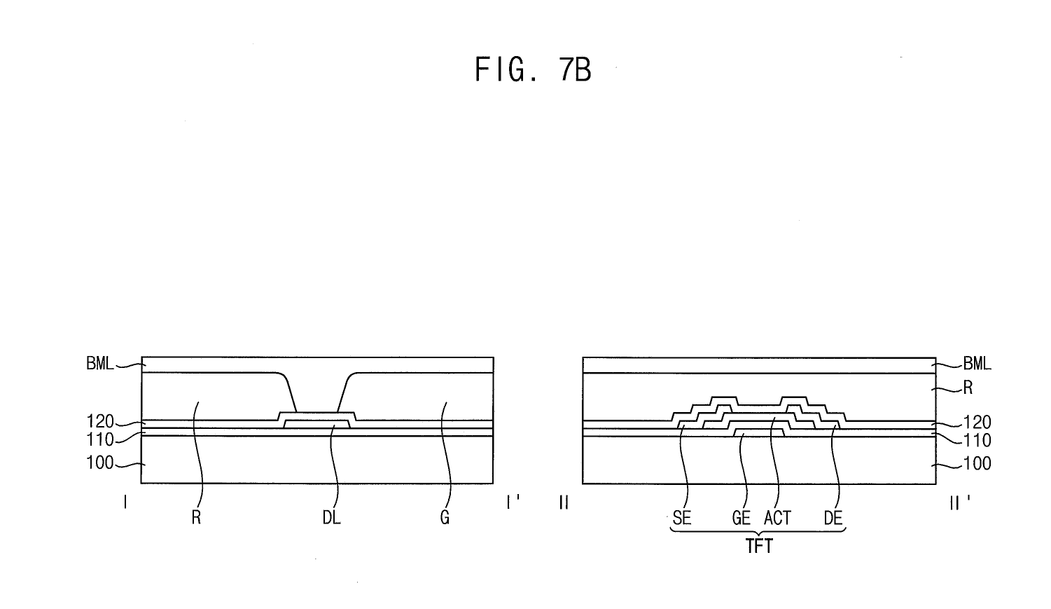

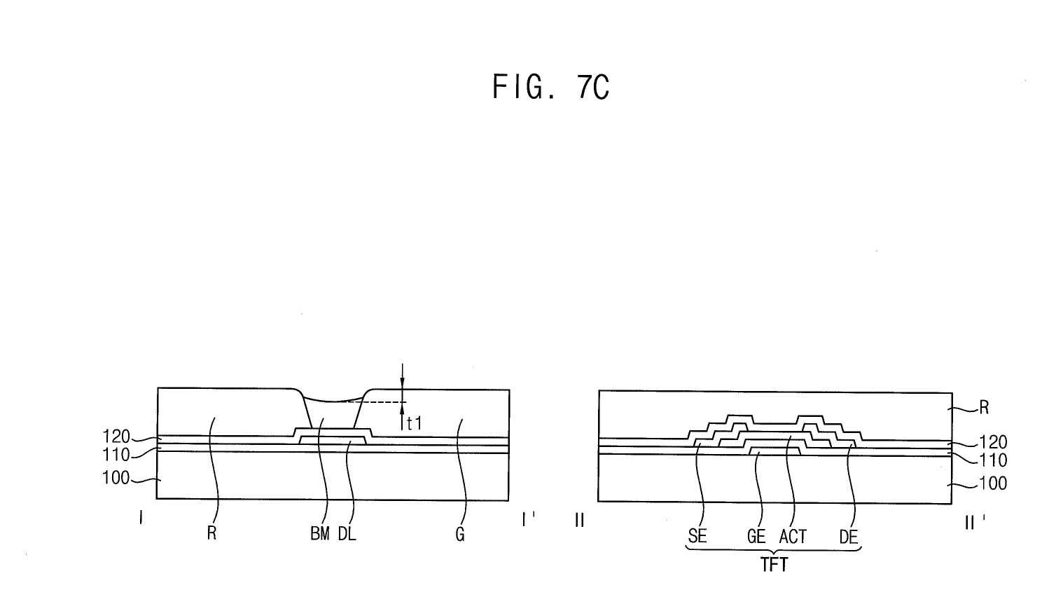

FIGS. 7A-7C are cross-sectional views illustrating another method of manufacturing the display apparatus of FIGS. 1-3. The method may be substantially same as a method of FIGS. 6A-6I except for forming light blocking material layer BML instead of light blocking material BM′ of FIG. 6E. Therefore, repeated description thereof will not be provided here.

Referring to FIG. 7A, a gate pattern may be formed on a lower substrate 100. A first insulation layer 110 may be formed on the lower base substrate 100 on which the gate pattern is formed. An active pattern and a data pattern may be formed on the first insulation layer 110. The data pattern may include a data line DL. A second insulation layer 120 may be formed on the first insulation layer 110 on which the data pattern and the active pattern are formed. A first color filter R, a second color filter G and a third color filter may be formed on the second insulation layer 120.

At this time, the first color filter R and the second color filter G (or the second color filter G and the third color filter, or the third color filter and the first color filter R) are spaced apart from each other on the data lien DL, so that a groove may be formed between the first color filter R and the second color filter G.

Referring to FIG. 7B, the light blocking material layer BML may be formed on the second insulation layer 120, and the first to third color filters R, G. The light blocking material layer BML may include light blocking material. The light blocking material may include a binder, a solvent and a black pigment such as carbon black. The light blocking material layer BML may fill the groove between the first color filter R and the second color filter G, and cover upper surfaces of the first color filter R and the second color filter G. For example, the light blocking material layer BML may be formed by slit coating process and the like.

Referring to FIG. 7C, the light blocking material layer BML may be developed using a developer to remove a portion of light blocking material layer BML. Accordingly, a light blocking pattern BM may be formed. The upper surface of the light blocking pattern BM may be lower than the upper surface of the first or second color filter R or G by a first height t1. Here, the light blocking pattern BM having proper height can be formed by changing development condition such as a type (or kind) of developer and developing time.

In addition, since the development process is continued until the upper surface of the light blocking pattern BM becomes lower than the upper surface of the first or second color filter R or G, the light blocking material layer that has remained unintentionally in a pixel area (refers to PA of FIG. 1) in which an image is displayed may be removed. Therefore, the light blocking material layer does not remain in the pixel area, so that the display quality can be improved.

And then, a pixel electrode and a column spacer may further formed on the first to third color filters R, G. A common electrode 210 may be formed on an upper substrate, and then a liquid crystal layer may be formed between the common electrode 210 and the pixel electrode PE. Therefore, the display apparatus may be manufactured

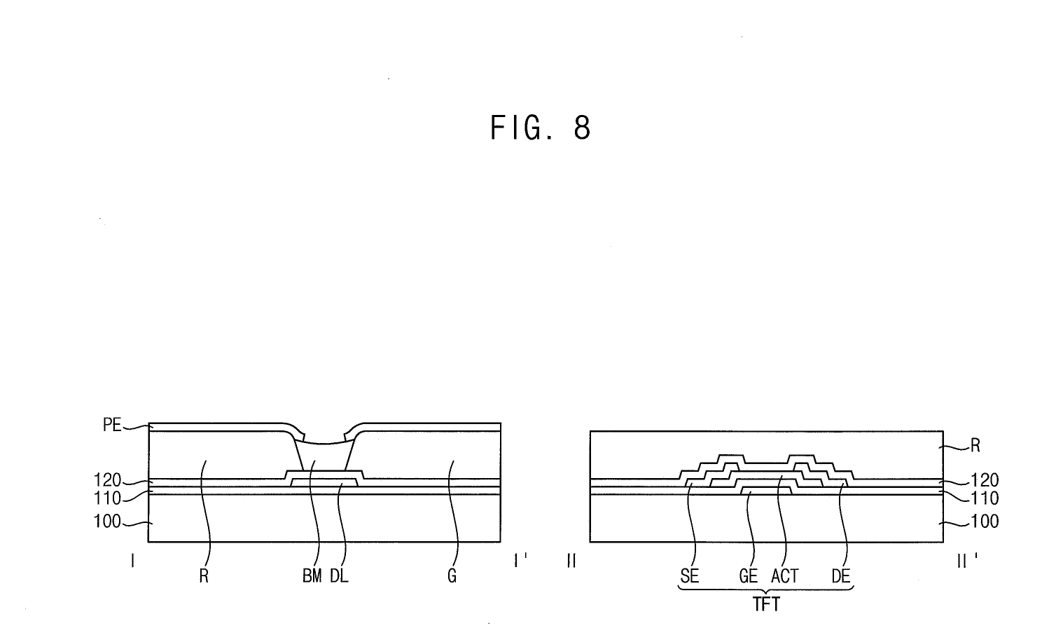

FIG. 8 is a cross-sectional view illustrating display apparatus of FIG. 4. The method may be substantially same as a method of FIGS. 6A-6I except that a pixel electrode PE partially overlaps a light blocking material BM. Therefore, repeated description thereof will not be provided here.

Referring to FIG. 8, a gate pattern may be formed on a lower substrate 100. A first insulation layer 110 may be formed on the lower base substrate 100 on which the gate pattern is formed. An active pattern and a data pattern may be formed on the first insulation layer 110. The data pattern may include a data line DL. A second insulation layer 120 may be formed on the first insulation layer 110 on which the data pattern and the active pattern are formed. A first color filter R, a second color filter G and a third color filter may be formed on the second insulation layer 120.

A pixel electrode PE may be formed on the first to third color filter R, G and the light blocking pattern BM. A transparent conductive layer may be formed on the first to third color filters R, G, and then the transparent conductive layer may be pattern to form the pixel electrode PE. The transparent conductive layer may be formed by a sputtering process, a CVD process, a PLD process, a vacuum evaporation process, an ALD process, a printing process, etc. Here, the light blocking pattern BM and the pixel electrode PE may be formed to overlap each other. Thus, an edge of the pixel electrode PE may make contact (e.g., physical contact) with the light blocking pattern BM.

And then, a column spacer may be formed on the first to third color filters R, G on which the pixel electrode PE is formed. A common electrode may be formed on an upper substrate, and then, a liquid crystal layer may be formed. Therefore, the display apparatus may be manufactured.

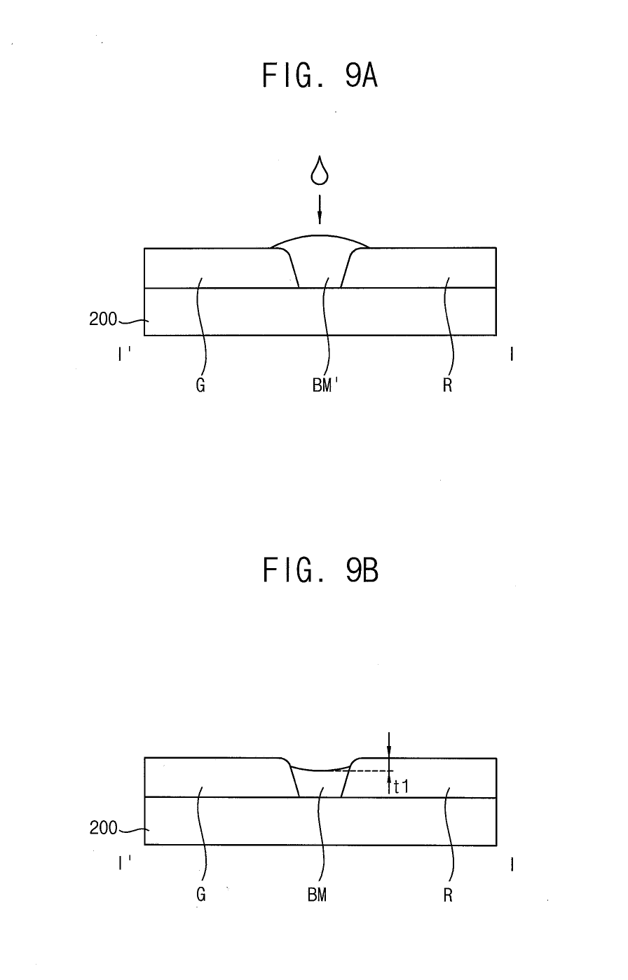

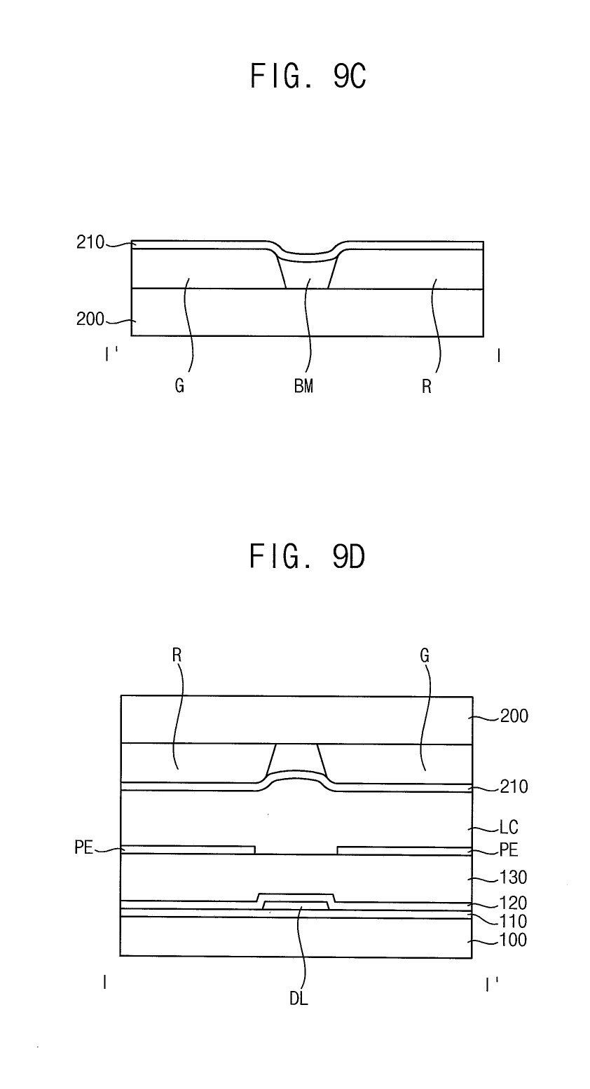

FIGS. 9A-9D are cross-sectional views illustrating another method of manufacturing the display apparatus of FIG. 5. The method may be substantially same as a method of FIGS. 6A-6I except that a color filter and a light blocking pattern are formed on an upper base substrate, and a third insulation layer 130 is further formed. Therefore, repeated description thereof will not be provided here.

Referring to FIG. 9A, a first color filter R, a second color filter G and a third color filter may be formed on an upper base substrate 200. A light blocking material BM′ may be provided to the groove which is between the first color filter R and the second color filter G on the upper base substrate 200 by an inkjet method. The light blocking material BM′ may include a binder, a solvent and a black pigment such as carbon black. Since the light blocking material BM′ does not require an exposure process for patterning, it may not include a photosensitive material such as a positive photoresist or a negative photoresist.

At this time, the light blocking material BM′ may be sufficiently provided to cover a portion of the upper surface of the first color filter R and the second color filter G. Accordingly, the upper surface of the light blocking material BM′ may be higher than the upper surface of the first color filter R and the upper surface of the second color filter G.

Referring to FIG. 9B, the light blocking material BM′ may be developed using a developer to remove an upper portion of the light blocking material BM′. Thus, the light blocking pattern BM may be formed. The upper surface of the light blocking pattern BM may be lower than the upper surface of the first or second color filter R or G by a first height t1. Here, the light blocking pattern BM having proper height can be formed by changing development condition such as a type (or kind) of developer and developing time.

Referring to FIG. 9C, the a common electrode 210 may be formed on the first to third color filters R, G and the light blocking pattern BM. The common electrode 210 may be formed by a sputtering process, a CVD process, a PLD process, a vacuum evaporation process, an ALD process, a printing process, etc.

Referring to FIG. 9D, a gate pattern may be formed on a lower substrate 100. A first insulation layer 110 may be formed on the lower base substrate 100 on which the gate pattern is formed. An active pattern and a data pattern may be formed on the first insulation layer 110. The data pattern may include a data line DL. A second insulation layer 120 may be formed on the first insulation layer 110 on which the data pattern and the active pattern are formed. A third insulation layer 130 may be formed on the second insulation layer 120. A pixel electrode and a column spacer may be formed on the third insulation layer 130. And then, a liquid crystal layer may be formed between the common electrode 210 and the pixel electrode PE. Therefore, the display apparatus may be manufactured.

According to the example embodiments of the present disclosure, a first color filter and a second color filter which is spaced apart from the first color filter are formed on a base substrate. A light blocking material is formed between the first and second color filters. The light blocking material is developed using a developer to remove an upper portion of the light blocking material, so that a light blocking pattern is formed. Accordingly a display apparatus may be manufactured.

At this time, since the development process is continued until the upper surface of the light blocking pattern becomes lower than the upper surface of the first or second color filter, the light blocking material that has remained unintentionally in a pixel area may be removed. Therefore, the light blocking material does not remain in the pixel area, so that the display quality can be improved.

In addition, since the light blocking pattern is formed by providing the light blocking material by the inkjet method and then developing it, a line width of the light blocking pattern may be smaller than that of other light blocking patterns formed by an inkjet method. Accordingly, the aperture ratio of the display apparatus may be improved, and the display quality can be improved.

In addition, an edge of the light blocking pattern proceeds in the developing process and the light blocking pattern is linearly formed along a second direction according to a shape of a groove formed between the first color filter and the second color filter. The quality of the shape of the light blocking pattern may be improved as compared with the case where the ink is dropped by the inkjet method. Accordingly, problems such as light leakage around the light blocking pattern may be solved, and the display quality of the display apparatus may be improved.

Unless otherwise noted, like reference numerals denote like elements throughout the attached drawings and the written description, and thus, descriptions thereof will not be repeated. In the drawings, the relative sizes of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, acts, operations, elements, and/or components, but do not preclude the presence or addition of one or more other features, integers, acts, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the terms “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The foregoing is illustrative of the subject matter of the present disclosure and is not to be construed as limiting thereof. Although a few example embodiments of the present disclosure have been described, those skilled in the art will readily appreciate that many modifications are possible in the example embodiments without materially departing from the novel teachings, advantages, and/or features of the present disclosure. Accordingly, all such modifications are intended to be included within the scope of the present disclosure as defined in the claims, and equivalents thereof. In the claims, means-plus-function clauses are intended to cover the structures described herein as performing the recited function and not only structural equivalents but also equivalent structures. Therefore, it is to be understood that the foregoing is illustrative of the subject matter of the present disclosure and is not to be construed as limited to the specific example embodiments disclosed, and that modifications to the disclosed example embodiments, as well as other example embodiments, are intended to be included within the scope of the appended claims. The subject matter of the present disclosure is defined by the following claims, with equivalents of the claims to be included therein.

What is claimed is:

1. A display apparatus comprising:
a first color filter;
a second color filter spaced apart from the first color filter; and
a light blocking pattern disposed between the first color filter and the second color filter, and making contact with the first color filter and the second color filter,
wherein a thickness of the light blocking pattern is smaller than a thickness of the first color filter or a thickness of the second color filter,
wherein an upper surface of the light blocking pattern is lower than an upper surface of the first or second color filter by a first height, and
wherein the light blocking pattern does not include a photosensitive material.

2. The display apparatus of claim 1, wherein the light blocking pattern is formed using a light blocking material which comprises a binder, a solvent and a black pigment.

3. The display apparatus of claim 2, wherein each of the thickness of the first color filter and the thickness of second color filter is about 1.0 to 4.0 μm, and the thickness of the light blocking pattern is about 0.3 to 4.0 μm.

4. The display apparatus of claim 1, further comprising:
a lower base substrate;
an upper base substrate facing the lower base substrate; and
a liquid crystal layer disposed between the lower base substrate and the upper base substrate,
wherein the first color filter and the second color filter are disposed between the lower base substrate and the liquid crystal layer.

5. The display apparatus of claim 4, further comprising a data line disposed between the lower base substrate and the light blocking pattern, and extending in a second direction which is perpendicular to a first direction.

6. The display apparatus of claim 5, further comprising a pixel electrode disposed on the first and second color filters, and
wherein the pixel electrode is spaced apart from the light blocking pattern.

7. The display apparatus of claim 6, wherein the pixel electrode partially overlaps the light blocking pattern, so that an edge of the pixel electrode makes contact with the light blocking pattern.

8. The display apparatus of claim 5, wherein the first filter extends in the second direction corresponding to a plurality of pixels, the second filter extends in the second direction corresponding to a plurality of pixels, and the first color filter and the second color filter are spaced apart from each other in the first direction.

9. The display apparatus of claim 8, further comprising a gate pattern comprising a gate electrode disposed between the first and second color filters and the lower base substrate,
wherein the gate electrode does not overlap the light blocking pattern, and overlap the first or second color filter.

10. The display apparatus of claim 9, wherein the gate pattern comprises molybdenum tantalum oxide (MoTaOx).

11. A method of manufacturing a display apparatus, comprising:
forming a first color filter and a second color filter on a base substrate, the second color filter being spaced apart from the first color filter on a base substrate;
forming a light blocking material between the first color filter and the second color filter; and
forming a light blocking pattern by removing an upper portion of the light blocking material using a developer.

12. The method of claim 11, wherein each of thickness of the first color filter and the thickness of second color filter is about 1.0 to 4.0 μm, and thickness of the light blocking pattern is about 0.3 to 4.0 μm.

13. The method of claim 11, wherein the light blocking material is provided between the first color filter and the second color filter by using an ink jet method during the forming of the light blocking material.

14. The method of claim 13, wherein the upper portion of the blocking material is removed until an upper surface of the light blocking pattern becomes lower than an upper surface of the first or second color filter by a first height during the forming of the light blocking pattern.

15. The method of claim 14, wherein forming the first and second color filter comprises:
coating a photosensitive resist on the base substrate, and forming the first color filter by exposure and development using a mask; and
coating a photosensitive resist on the base substrate on which the first color filter is formed, and forming the second color by exposure and development using a mask.

16. The method of claim 11, wherein a light blocking layer covers upper surfaces of the first and second color filters in during forming the light blocking material.

17. The method of claim 11, wherein the base substrate is a lower base substrate, the method further comprises:
preparing an upper base substrate; and
forming a liquid crystal layer between the upper base substrate and the lower base substrate.

18. The method of claim 11, further comprising forming a data pattern comprising a data line on the base substrate before forming the first and second color filters,
wherein the data line overlaps the light blocking pattern.

19. The method of claim 18, further comprising forming a gate pattern comprising a gate electrode on the base substrate before forming the first and second color filters,
wherein the gate electrode does not overlap the light blocking pattern, and overlaps the first or second color filter.

20. The method of claim 19, wherein the gate pattern comprises molybdenum tantalum oxide (MoTaOx).
